(19) United States
(12) Patent Application Publication
(10) Pub. No.: US 2013/0049557 A1
(43) Pub. Date: Feb. 28, 2013

(54) DEVICE HOUSING AND METHOD FOR MAKING THE DEVICE HOUSING

(71) Applicants: PO-FENG HO, Shindian (TW); XIN-WU GUAN, Shenzhen City (CN); CHAO-SHENG HUANG, Shenzhen City (CN)

(72) Inventors: PO-FENG HO, Shindian (TW); XIN-WU GUAN, Shenzhen City (CN); CHAO-SHENG HUANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/332,583

(22) Filed: Dec. 21, 2011

(30) Foreign Application Priority Data
Aug. 25, 2011 (CN) 201110246265.6

(51) Int. Cl. H05K 5/02; B05D 3/06; B05D 5/00; B05D 3/10

(52) U.S. Cl. 312/223.2; 216/39; 427/556

(57) ABSTRACT

A device housing includes a stainless steel substrate having a first metallic coating and a second metallic coating formed thereon and in that order. The stainless steel substrate has at least one recess defined in an outer surface. The first metallic coating and a second metallic coating have different colors. The first metallic coating is left exposed in the recesses but covered elsewhere by the second metallic coating to form a desired symbol, logo, or pattern on the device housing. A method for making the present device housing also is provided.

### BACKGROUND

1. Technical field

The present disclosure relates to housings for electronic devices and a method for making housings having patterns or logos.

2. Description of related art

Shells for portable electronic devices are usually decorated with symbols, logos, or patterns to attract consumers. A typical method for making these decorations on a stainless steel shell includes the following steps: polishing, sandblasting, or hairline finishing the surface of a stainless steel substrate; then laser etching, chemical etching, or milling the surface to form a logo or symbol pattern. However, logos or symbols formed by such methods usually are not sufficiently glossy. Moreover, it is hard to polish such logos or symbols by typical mechanical treatment.

Therefore, there is room for improvement within the art.

### BRIEF DESCRIPTION OF THE DRAWINGS

Many aspects of the present disclosure can be better understood with reference to the drawings. The components in the drawings are not necessarily drawn to scale, the emphasis instead being placed upon clearly illustrating the principles of the disclosure.

Moreover, in the drawings like reference numerals designate corresponding parts throughout the views.

FIG. 1 is a cross-section view of the present housing according to an exemplary embodiment.

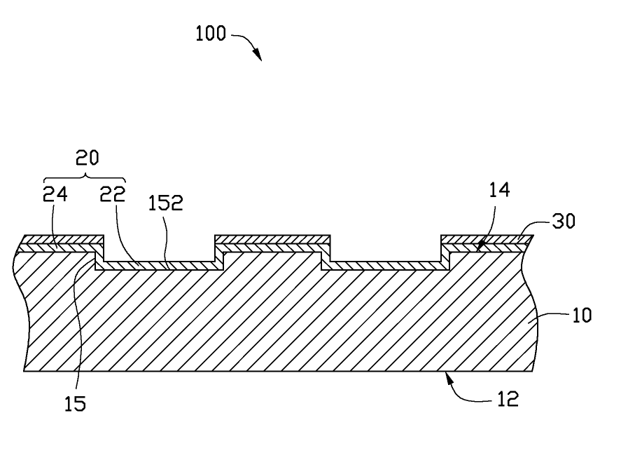

### DETAILED DESCRIPTION

The figure shows an exemplary device housing 100 for electronic devices (such as mobile phones). In this exemplary embodiment, the device housing 100 is a cover of a mobile phone. The device housing 100 includes a stainless steel substrate 10 having a first metallic coating 20 and a second metallic coating 30 formed on the first metallic coating 20.

The stainless steel substrate 10 includes an inner surface 12 and an outer surface 14 opposite to the inner surface 12. The outer surface 14 defines at least one recess 15. In this embodiment, the outer surface 14 defines a plurality of recesses 15. The recesses 15 cooperatively depict a desired symbol, logo, or pattern on the outer surface 14. In this exemplary embodiment, each of the recesses 15 has a depth of about 0.15 mm. Each of the recesses 15 has a bottom wall 152 smoother than the outer surface 14. The bottom walls 152 of the recesses 15 may be pretreated by an electrochemical polishing process. The outer surface 14 may have a sandblasted pattern or a brushed texture of very fine lines, achieved by a sandblasting process or a hairline finishing process.

The first metallic coating 20 may be formed on the outer surface 14 and in the recesses 15. The first metallic coating 20 includes a first portion 22 and a second portion 24 connecting with the first portion 22. The first portion 22 is formed in the recesses 15 and the second portion 24 is formed on the outer surface 14. Because the bottom walls 152 of the recesses 15 are smoother than the outer surface 14, thus the first portion 22 is smoother than the second portion 24. Accordingly, the first portion 22 has a high gloss. The first metallic coating 20 has a thickness less than the depth of the recesses 15.

The second metallic coating 30 is applied only to the second portion 24, so that the first metallic coating 20 in the recesses 15 is exposed and viewed in contrast to the second metallic coating 30, forming a desired symbol, logo, or pattern on the device housing 100. The second metallic coating 30 has a color different from that of the first metallic coating 20. Because the outer surface 14 has a sandblasted pattern or a brushed texture of very fine lines, accordingly, the second metallic coating 30 thereby has a surface profile corresponding to the outer surface 14, having a sandblasted pattern or a brushed texture of very fine lines. Thus, the second metallic coating 30 has a relative low gloss.

The first metallic coating 20 and the second metallic coating 30 may both be made of one or more materials selected from the group consisting of oxide of metal, nitride of metal, carbide of metal, carbonitride of metal, and oxynitride of metal, and may be formed by physical vapor deposition (PVD). In this embodiment, the first metallic coating 20 is made of nitride of metal formed by a PVD process and presents a golden color, while the first metallic coating 20 is made of carbonitride of metal formed by a PVD process and presents a black color.

The first metallic coating 20 and the second metallic coating 30 have different colors, achieving a dual-color appearance on the device housing 100. Moreover, the first portion 22 of the first metallic coating 20 visible in the recesses 15 has a high gloss, while the second metallic coating 30 has a surface profile corresponding to the outer surface 14. The outer surface 14 has a sandblasted pattern or a brushed texture of very fine lines, and thus the second metallic coating 30 has a relatively low gloss providing even greater contrast with the first metallic coating 20 then color alone would provide. Furthermore, because the thickness of the first metallic coating 20 is less than the depth of the recesses 15 the first metallic coating 20 is not easily abraded.

An exemplary method for making the device housing 100 may include the following steps.

The stainless steel substrate 10 having the inner surface 12 and the outer surface 14 is provided. The stainless steel substrate 10 may be manufactured by, for example, stamping.

The recesses 15 having the bottom walls 152 may be defined in the substrate 10 by chemical etching or laser engraving the outer surface 14. In this embodiment, the recesses 15 are formed by chemical etching. The outer surface 14 besides portions to form the recesses 15 may be masked using masking materials, such as chemical resistant inks, protecting the outer surface 14 besides portions to form the recesses 15 from damage during the chemical etching.

The substrate 10 is electrochemically polished, smoothing the outer surface 14 and the bottom walls 152.

The substrate 10 is processed by sandblasting or hairline finishing, forming a sandblasted pattern or a brushed texture of very fine lines on the outer surface 14. In order to protect the bottom walls 152 of the recesses 15 from damage during the sandblasting process or hairline finishing process, masking material, such as ink may be filled in the recesses 15 and then removed before the subsequently first PVD process.

The outer surface 14 is processed by a first PVD process, forming the first metallic coating 20 on the outer surface 14 and in the recesses 15. The physical vapor deposition may be magnetron sputtering or arc ion plating, using metal as target and one or more of the nitrogen, oxygen, and acetylene as reaction gas. The first metallic coating 20 includes a first portion 22 and a second portion 24 connecting with the first portion 22. The first portion 22 is formed in the recesses 15 and the second portion 24 is formed on the outer surface 14.

The recesses 15 may be masked with ink, protecting them from being coated during the followed second PVD process.

The substrate 10 is processed by a second PVD process, forming the second metallic coating 30 on the second portion 24 of the first metallic coating 20. The physical vapor deposition may be magnetron sputtering or arc ion plating, using metal as target and one or more of the nitrogen, oxygen, and acetylene as reaction gas. The second metallic coating 30 has a different color from the first metallic coating 20.

The ink is removed from the recesses 15, exposing the first portion of the first metallic coating 20 just at the recesses. The ink may be removed by cleaning with a chemical agent.

In order to protect the bottom walls 152 of the recesses 15 from damage during the sandblasting process or hairline finishing process, masking material, such as ink may be filled in the recesses 15 before sandblasting or hairline finishing the outer surface 14, and then removed before the first PVD process.

However, even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing, comprising:
a stainless steel substrate having at least one recess defined in an outer surface;
a first metallic coating having a firs portion and a second portion connecting the first portion, the first portion formed in the recesses, the second portion formed on the outer surface; and
a second metallic coating applied only to the second portion, the second metallic coating and first metallic coating having different colors from each other.

2. The device housing as claimed in claim 1, wherein the outer surface has a sandblasted pattern or a brushed texture of fine lines achieved by a sandblasting process or a hairline finishing process, the second metallic coating thereby has a surface profile corresponding to the outer surface, having a sandblasted pattern or a brushed texture of very fine lines.

3. The device housing as claimed in claim 1, wherein each of the at least one recess has a bottom wall smoother than the outer surface.

4. The device housing as claimed in claim 1, wherein the first metallic coating and the second metallic coating both are made of one or more selected from the group consisting of oxide of metal, nitride of metal, carbide of metal, carbonitride of metal, and oxynitride of metal, which is formed by physical vapor deposition.

5. The device housing as claimed in claim 1, wherein the first metallic coating has a thickness less than the depth of the at least one recess.

6. The device housing as claimed in claim 1, wherein the first portion of the first metallic coating forms a symbol, logo, or pattern on the device housing.

7. A method for making a device housing, comprising:
providing a stainless steel substrate having an outer surface;
defining at least one recess in the outer surface by chemically etching or laser engraving, each of the at least one recess having a bottom wall;
forming a first metallic coating on the stainless steel substrate by a first physical vapor deposition process, the first metallic coating having a firs portion and a second portion connecting the first portion, the first portion formed in the at least one recess, the second portion formed on the outer surface;
masking the at least one recess with ink;
forming a second metallic coating on the second portion of the first metallic coating by a second physical vapor deposition process, the second metallic coating and the first metallic coating having different colors from each other; and
removing the ink, exposing the first portion of the first metallic coating out of the second metallic coating.

8. The method as claimed in claim 7, further comprising a step of electrochemically polishing the stainless steel substrate before the step of defining the at least one recess, smoothing the outer surface and the bottom wall of the at least one recess.

9. The method as claimed in claim 8, further comprising a step of sandblasting or hairline finishing the outer surface before the step of forming the first metallic coating, forming a sandblasted pattern or a brushed texture of fine lines on the outer surface.

10. The method as claimed in claim 7, further comprising a step of filling masking material in the recesses before sandblasting or hairline finishing the outer surface.

11. The method as claimed in claim 7, wherein the ink is removed by cleaning with chemical agent.
